(19) United States
(12) Patent Application Publication
(10) Pub. No.: US 2022/0137153 A1
(43) Pub. Date: May 5, 2022

(54) MANAGEMENT METHOD, MANAGEMENT DEVICE, MANAGEMENT SYSTEM AND NON-TRANSITORY STORAGE MEDIUM

(71) Applicant: KABUSHIKI KAISHA TOSHIBA, Tokyo (JP)

(72) Inventors: Tomokazu Morita, Funabashi Chiba (JP); Nobukatsu Sugiiyama, Kawasaki Kanagawa (JP); Yumi Fujita, Tokyo (JP)

(73) Assignee: KABUSHIKI KAISHA TOSHIBA, Tokyo (JP)

(21) Appl. No.: 17/576,530

(22) Filed: Jan. 14, 2022

Related U.S. Application Data
(63) Continuation of application No. PCT/JP2021/008319, filed on Mar. 4, 2021.

(30) Foreign Application Priority Data
Jul. 13, 2020 (JP) 2020-120022

(51) Int. Cl. G01R 31/396; H02J 7/00; G01R 31/392; H01M 10/42

(52) U.S. Cl. CPC G01R 31/396; H02J 7/005; H01M 2010/4271; H01M 10/4257; G01R 31/392

(57) ABSTRACT

According to one embodiment, a management method of a storage battery including a plurality of batteries is provided. In the management method, replacement data is generated based on at least an estimation result of an internal state of each of the batteries, and deterioration rate data indicative of a deterioration rate of battery characteristics in each of the batteries, the deterioration rate data being based on the estimation result of the internal state. The replacement data includes information indicative of a target battery which is a target of replacement among the batteries, information relating to a battery with which the target battery is replaced, and information relating to a time of replacement of the target battery.

### CROSS-REFERENCE TO RELATED APPLICATIONS

This is a Continuation Application of PCT Application No. PCT/JP2021/008319, filed Mar. 4, 2021 and based upon and claiming the benefit of priority from prior Japanese Patent Application No. 2020-120022, filed Jul. 13, 2020, the entire contents of which are incorporated herein by reference.

### FIELD

Embodiments described herein relate to a management method, a management device, a management system and a non-transitory storage medium.

### BACKGROUND

In recent years, a storage battery has been mounted in battery-mounted devices such as a smartphone, a vehicle, a stationary power source device, a robot and a drone. In such a storage battery, a large number of batteries, such as lithium ion batteries, are provided, and the large number of batteries are electrically connected. In addition, a management system which manages the storage battery has been developed.

If the storage battery as described above is used for a long time, the deterioration degree of battery characteristics varies among the batteries because, for example, the positions of disposition of the batteries are different. In addition, in the storage battery, if a management system or the like determines that the life of one battery ended, the use of the storage battery is terminated even if the other batteries are usable. Thus, it is required to properly replace a target battery, which is a target of replacement, before the variance of the deterioration degree of battery characteristics increases among the batteries. Further, it is required to suppress the variance of battery characteristics among the batteries to a low level for a long time by the replacement of the target battery, and to increase the life of the storage battery.

### BRIEF DESCRIPTION OF THE DRAWINGS

FIG. 1 is a schematic view illustrating an example of a management system according to an embodiment.

FIG. 2 is a schematic view for explaining internal state parameters indicative of the internal state in each of batteries.

FIG. 3 is a schematic view illustrating an example of variations with time, from the start of use of a storage battery, of battery capacitances estimated in regard to three batteries of the storage battery.

FIG. 4 is a schematic view illustrating variations with time, from the start of use of the storage battery, of positive electrode capacitances estimated in regard to the three batteries shown in the example of FIG. 3.

FIG. 5 is a schematic view illustrating an example of deterioration rate data which a deterioration rate data generation unit of a management device according to the embodiment generates.

FIG. 6 is a schematic view for explaining an example of the estimation of life end time points of a plurality of batteries in a case where the deterioration rate data of the example of FIG. 5 was generated.

FIG. 7 is a schematic view illustrating an example of effect data in a case where replacement data was generated based on the deterioration rate data of the example of FIG. 5.

FIG. 8 is a flowchart illustrating a process which is executed by the management device according to the embodiment.

### DETAILED DESCRIPTION

According to one embodiment, a management method of a storage battery including a plurality of batteries is provided. In the management method, replacement data is generated based on at least an estimation result of an internal state of each of the batteries, and deterioration rate data indicative of a deterioration rate of battery characteristics in each of the batteries, the deterioration rate data being based on the estimation result of the internal state. The replacement data includes information indicative of a target battery which is a target of replacement among the batteries, information relating to a battery with which the target battery is replaced, and information relating to a time of replacement of the target battery. The replacement data is generated at a timing when the battery characteristics in each of the batteries do not exhibit a tendency of deterioration and the internal state in any one or more of the batteries exhibits a tendency of deterioration.

Hereinafter, embodiments will be described with reference to the accompanying drawings.

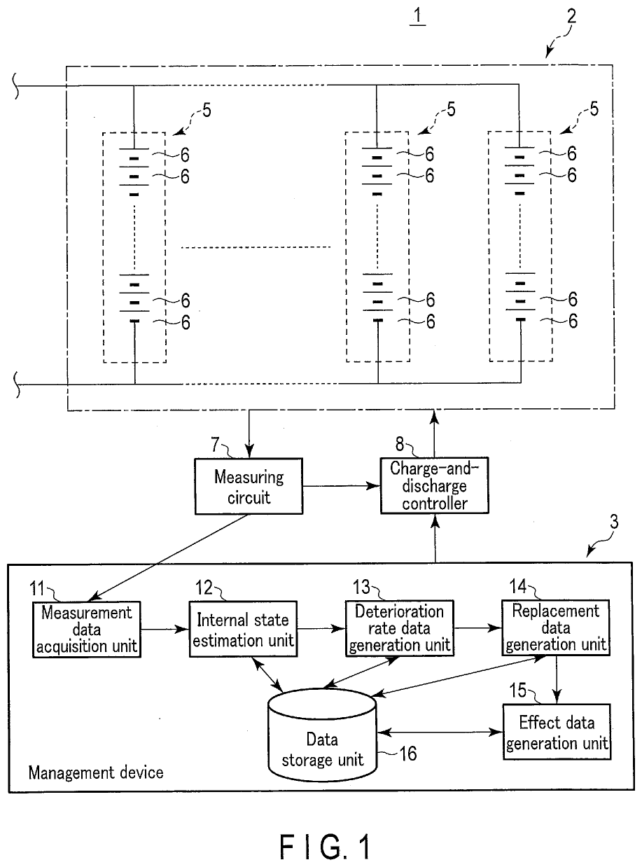

FIG. 1 is a schematic view illustrating an example of a management system according to an embodiment. As illustrated in FIG. 1, a management system 1 includes a storage battery 2 and a management device 3. The storage battery 2 is mounted, for example, in a battery-mounted device. Examples of the battery-mounted device include a large-sized storage battery for an electric power system, a smartphone, a vehicle, a stationary power source device, a robot, a drone, and the like. Examples of the vehicle, which is the battery-mounted device, include a railway vehicle, an electric bus, an electric automobile, a plug-in hybrid automobile, an electric bicycle, and the like.

In the example of FIG. 1, the storage battery 2 includes a plurality of battery strings 5. In the storage battery 2, the battery strings 5 are electrically connected in parallel. Each of the battery strings 5 includes a plurality of batteries 6, and the batteries 6 are electrically connected in series in each of the battery strings 5. In the storage battery 2, each of the batteries 6 is chargeable and dischargeable. In each battery string 5, each battery 6 is charged by being supplied with electric power from a power source. In addition, in each battery string 5, electric power discharged from each battery 6 is supplied to a load. Note that in the storage battery 2, batteries of an identical kind to each other are used as the batteries 6. Thus, when the use of the storage battery 2 is started, the batteries 6 have identical or substantially identical internal states and battery characteristics to each other. The internal states and battery characteristics of the batteries 6 will be described later.

Each of the batteries 6 may be formed of a unit cell (unit battery), or may be a battery module or a cell block, which is formed by a plurality of unit cells being electrically connected. Here, the unit cell is, for example, a cell of a lithium ion secondary battery. When each of the batteries 6 is formed of a plurality of unit cells, the unit cells may be electrically connected in series in each battery 6, or the unit cells may be electrically connected in parallel in each battery 6. Besides, in each battery 6, both of a series-connected structure in which a plurality of unit cell are connected in series, and a parallel-connected structure in which plurality of unit cell are connected in parallel, may be formed.

In the management system 1, a measuring circuit 7 and a charge-and-discharge controller 8 are provided. The measuring circuit 7 and charge-and-discharge controller 8 are mounted, for example, in a battery-mounted device. The measuring circuit 7 detects and measures parameters relating to the storage battery 2 in the charge or discharge of the storage battery 2. In the measuring circuits 7, the parameters are detected and measured periodically at a predetermined timing. Specifically, the measuring circuit 7 measures the parameters relating to the storage battery 2 at each of a plurality of measuring time points. Thus, the measuring circuit 7 measures multiple times the parameters relating to the storage battery 2 in the charge or discharge of the storage battery 2. Note that a time point at which the measuring circuit 7 executes the measurement in the charge or discharge of the storage battery 2 is defined as “measuring time point”. The parameters relating to the storage battery 2 include an electric current flowing in each of the batteries 6, a voltage of each of the batteries 6, and a temperature of each of the batteries 6. Thus, the measuring circuit 7 includes an amperemeter which measures the current, a voltmeter which measures the voltage, and a temperature sensor which measures the temperature. Here, in the example of FIG. 1, mutually identical electric currents flow in the batteries 6 which constitute an identical battery string 5. Thus, in the example of FIG. 1, the current may be detected in regard to each of the battery strings 5.

The charge-and-discharge controller 8 constitutes a processing device (computer) which controls the charge and discharge of the storage battery 2, i.e. the charge and discharge of the batteries 6, and includes a processor and a storage medium (non-transitory storage medium). The processor includes any one of a CPU (Central Processing Unit), a GPU (Graphics Processing Unit), an ASIC (Application Specific Integrated Circuit), a microcomputer, an FPGA (Field Programmable Gate Array), and a DSP (Digital Signal Processor), and the like. The storage medium may include an auxiliary storage device, in addition to a main storage device such as a memory. Examples of the storage medium include a magnetic disk, an optical disc (e.g. CD-ROM, CD-R, DVD), a magneto-optical disc (e.g. MO), and a semiconductor memory. In the charge-and-discharge controller 8, each of the number of processors and the number of storage media may be one or plural. In the charge-and-discharge controller 8, the processor executes a process by executing a program or the like stored in the storage medium or the like. In addition, in the charge-and-discharge controller 8, the program that is executed by the processor may be stored in a computer (server) connected via a network such as the Internet, or may be stored in a server or the like in a cloud environment. In this case, the processor downloads the program via the network.

The management device 3 may be provided in the battery-mounted device in which the storage battery 2 is mounted, or may be provided outside the battery-mounted device. The management device 3 manages the entirety of the management system 1 including the storage battery 2, and includes a measurement data acquisition unit 11, an internal state estimation unit 12, a deterioration rate data generation unit 13, a replacement data generation unit 14, an effect data generation unit 15, and a data storage unit 16. In one example, the management device 3 is a server which can communicate with the charge-and-discharge controller 8 via a network. In this case, like the charge-and-discharge controller 8, the management device 3 includes a processor and a storage medium (non-transitory storage medium). In addition, the measurement data acquisition unit 11, internal state estimation unit 12, deterioration rate data generation unit 13, replacement data generation unit 14 and effect data generation unit 15 execute a part of processes which are executed by the processor or the like of the management device 3, and the storage medium of the management device 3 functions as the data storage unit 16. In another example, the management device 3 is a cloud server constituted in a cloud environment. The infrastructure of the cloud environment is constituted by a virtual processor, such as a virtual CPU, and a cloud memory. Thus, when the management device 3 is the cloud server, the measurement data acquisition unit 11, internal state estimation unit 12, deterioration rate data generation unit 13, replacement data generation unit 14 and effect data generation unit 15 execute a part of processes which are executed by the virtual processor. Further, the cloud memory functions as the data storage unit 16.

Note that the data storage unit 16 may be provided in a computer which is different from the charge-and discharge controller 8 and management device 3. In this case, the management device 3 is connected via a network to a computer in which the data storage unit 16 or the like is provided. In addition, the management device 3 may employ the charge-and discharge controller 8 as a slave control device, and may cooperate with the charge-and discharge controller 8, thus controlling the charge and discharge of the storage battery 2. Hereinafter, a process of the management device 3 will be described.

When the management device 3 executes a process, the charge-and-discharge controller 8 charges or discharges each of the batteries 6 of the storage battery 2. In addition, the measuring circuit 7 measures the above-described parameters relating to the storage battery 2 in the charge or discharge of each battery 6. Then, the measurement data acquisition unit 11 of the management device 3 acquires, as measurement data, measurement values in the measuring circuit 7 of the parameters relating to the storage battery 2. Thus, the measurement data acquisition unit 11 acquires an electric current flowing in each of the batteries 6, a voltage of each of the batteries 6, and a temperature of each of the batteries 6. The measurement data acquisition unit 11 periodically acquires at a predetermined timing the measurement values of the parameters relating to the storage battery 2. Specifically, the measurement data acquisition unit 11 acquires the measurement values of the parameters relating to the storage battery 2 in regard to each of a plurality of measuring time points (measurements of multiple times). Thus, the measurement data acquisition unit 11 also acquires, as measurement data, a time variation (time history) of parameters relating to the storage battery 2, in addition to the measurement values of the parameters relating to the storage battery 2. Accordingly, the measurement data that the measurement data acquisition unit 11 acquires includes the time variation (time history) of the current flowing in each battery 6, the time variation (time history) of the voltage of each battery 6, and the time variation (time history) of the temperature of each battery 6.

Besides, the measurement data acquisition unit 11 acquires charge conditions or discharge conditions at a time of measuring the parameters relating to the storage battery 2, in addition to the above-described measurement data. The charge conditions include a charge current value, an SOC (State of Charge) of each battery 6 at the start of charge and at the end of charge, and the temperature range of each battery 6 at the time of charge. Similarly, the discharge conditions include a discharge current value, the SOC of each battery 6 at the start of discharge and at the end of discharge, and the temperature range of each battery 6 at the time of discharge.

The measurement data acquisition unit 11 may acquire, as measurement data, data indicative of a relationship of the voltage to either a charge amount (discharge amount) from the start of charge (the start of discharge) or the SOC in regard to each of the batteries 6. For each battery 6, the charge amount (discharge amount) from the start of charge (start of discharge) can be calculated by using the elapsed time from the start of charge (start of discharge) and the time variation (time history) of the flowing current. In addition, in the example of FIG. 1, or the like, because of the configuration in which the batteries 6 are connected in series in the battery string 5, the charge amount (discharge amount) of the battery string 5 from the start of charge (start of discharge) corresponds to the charge amount (discharge amount) from the start of charge (start of discharge) of the battery 6 as an elemental battery, which constitutes the battery string 5.

In each of the batteries 6, the ratio of the residual capacitance until the SOC reaches 0% to the full-charge capacitance until the SOC reaches 100% from 0% is defined as the SOC. For each battery 6, the SOC can be calculated by using the above-described measurement data, and the charge/discharge history or the like. Examples of the method of calculating the SOC of each battery 6 include a current integration method, a calculation method using the relationship between the inter-terminal voltage of the elemental battery 6 and the SOC, and an estimation method using a Kalman filter. In each of the batteries 6, the state in which the inter-terminal voltage (the voltage between the positive electrode terminal and the negative electrode terminal) has a voltage value Vα1 under set discharge conditions is defined as the state in which the SOC is 0%, and the state in which the inter-terminal voltage has a voltage value Vα2, which is greater than the voltage value Vα1, under set charge conditions is defined as the state in which the SOC is 100%.

As described above, the measurement data acquisition unit 11 acquires the measurement data, for example, by receiving the measurement data, and thereby the management device 3 acquires the data indicative of the measurement values of the parameters relating to the storage battery 2 in each of multiple measurements. Besides, the measurement data may be acquired by the charge-and-discharge controller 8. In this case, the charge-and-discharge controller 8 controls the charge or discharge of each battery 6, based on the measurement data.

The internal state estimation unit 12 executes a process by using, for instance, the measurement data which the measurement data acquisition unit 11 acquired. The internal state estimation unit 12 estimates the internal state of each battery 6, based on the measurement data. In the present embodiment, the internal state estimation unit 12 estimates an internal state parameter indicative of an internal state in regard to each of the batteries 6. In one example, the internal state estimation unit 12 analyzes data representing a relationship of each of the voltage and current to the charge time (discharge time) for each of the batteries 6. Accordingly, for each battery 6, data indicative of measurement values of the voltage and current in each of multiple measurements, i.e. data indicative of a time variation of the voltage and a time variation of the current, is analyzed by the internal state estimation unit 12. Thus, charge curve analysis (discharge curve analysis) in regard to each battery 6 is performed by the internal state estimation unit 12.

Here, in each of the batteries 6, the internal state parameters include, for example, any one of a positive electrode capacitance (or a positive electrode mass), a negative electrode capacitance (or a positive electrode mass), an initial charge amount of the positive electrode, an initial charge amount of the negative electrode, and an internal resistance. In addition, the internal state parameters of each battery 6 may include an SOW (Shift of Operation Window) which is a shift between the initial charge amount of the positive electrode and the initial charge amount of the negative electrode.

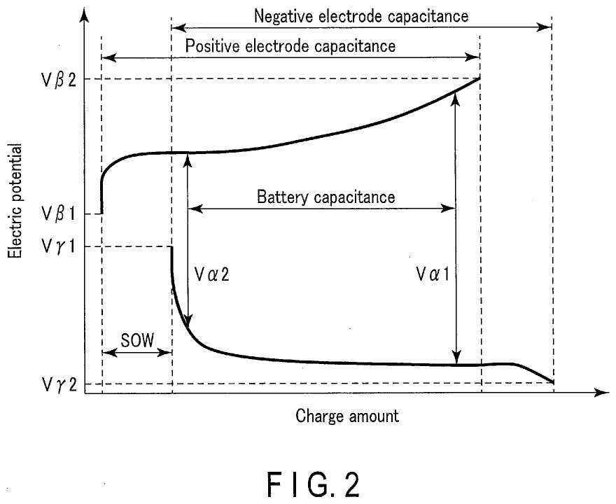

FIG. 2 is a schematic view for explaining the internal state parameters indicative of the internal state in each of the batteries. As shown in FIG. 2, in the elemental battery 6, a charge amount until the charge amount of the positive electrode reaches an upper-limit charge amount from an initial charge amount is a positive electrode capacitance. In addition, a charge amount of the positive electrode in a state in which the positive electrode potential (the electric potential of the positive electrode terminal) becomes Vβ1 is defined as the initial charge amount, and a charge amount of the positive electrode in a state in which the positive electrode potential becomes Vβ2, which is higher than Vβ1, is defined as the upper-limit charge amount. Besides, in the elemental battery 6, a charge amount until the charge amount of the negative electrode reaches an upper-limit charge amount from an initial charge amount is a negative electrode capacitance. In addition, a charge amount of the negative electrode in a state in which the negative electrode potential (the electric potential of the negative electrode terminal) becomes Vγ1 is defined as the initial charge amount, and a charge amount of the negative electrode in a state in which the negative electrode potential becomes Vγ2, which is lower than Vγ1, is defined as the upper-limit charge amount. Further, the positive electrode mass can be estimated from the estimated positive electrode capacitance and the kind of material, of which the positive electrode is formed. Similarly, the negative electrode mass can be estimated from the estimated negative electrode capacitance and the kind of material, of which the negative electrode is formed.

In addition, the internal state parameters of each battery 6 may include a positive electrode capacity retention ratio and a negative electrode capacity retention ratio. Here, the positive electrode capacity retention ratio is the ratio of the estimated positive electrode capacitance to the positive electrode capacitance at the time of the start of use, and the negative electrode capacity retention ratio is the ratio of the estimated negative electrode capacitance to the negative electrode capacitance at the time of the start of use. In each of the batteries 6, if deterioration occurs due to repetitive charge and discharge, each of the above-described positive electrode capacitance and negative electrode capacitance decreases, compared to when the use thereof was started, and the positive electrode capacity retention ratio and the negative electrode capacity retention ratio deteriorate. Further, in each battery 6, if deterioration occurs, the above-described SOW varies from the time of the start of use.

In addition, for each of the batteries 6, the internal state estimation unit 12 estimates a battery characteristic parameter, based on the estimated internal state parameter, i.e., based on the estimation result of the internal state. Thereby, the battery characteristics of each battery 6 are estimated by the internal state estimation unit 12. The battery characteristic parameters of each battery 6 include a battery capacitance, an open circuit voltage (OCV) and an OCV curve. The battery capacitance corresponds to a charge amount until the difference between the positive electrode potential and the negative electrode potential reaches Vα2 from Vα1 (see FIG. 2). The OCV curve is a function indicative of a relationship of the OCV to a parameter other than the OCV, for example, a function indicative of a relationship of the OCV to the SOC or the charge amount. In addition, in each of the batteries 6, the internal resistance, which is one of the internal state parameters, is also a battery characteristic parameter indicative of battery characteristics.

The data storage unit 16 stores arithmetic data which is used in arithmetic operations in the above-described estimation of the internal state parameters and the battery characteristic parameters. The internal state estimation unit 12 reads arithmetic data, which is necessary for the estimation of the internal state parameters or the like, from the data storage unit 16. The arithmetic data includes, for example, a function indicative of the OCP (Open Circuit Potential) of the positive electrode relative to the SOC of the positive electrode in each of the batteries 6, and a function indicative of the OCP of the negative electrode relative to the SOC of the negative electrode in each of the batteries 6. In addition, in the estimation of the above-described internal state parameters, interim estimation values or the like are calculated in a process of obtaining an ultimate estimation result. The above-described arithmetic data may include an interim estimation value of each of the internal state parameters. Besides, the internal state estimation unit 12 can store, in the data storage unit 16, those estimation values, among the interim and ultimate estimation values of the internal state parameters, which become necessary in the subsequent estimation process.

Note that the estimation of the internal state parameters of an elemental battery by charge curve analysis is disclosed in, for example, a reference literature 1 (Jpn. Pat. Appin. KOKAI Publication No. 2018-147827). In the present embodiment, for example, like the charge curve analysis of the reference literature 1, the above-described internal state parameters are estimated for each battery 6. In addition, the estimation of the battery characteristic parameters based on the internal state parameters may be performed in the same manner as described in the reference literature 1. For example, when the OCV curve is estimated as the battery characteristic parameter, an upper-limit voltage and a lower-limit voltage, which are imposed on the OCV in regard to each of the batteries 6, are stored in the data storage unit 16 as arithmetic data.

If the storage battery 2 or the like is used for a long time without replacing any one of the batteries 6, the deterioration degree of battery characteristics varies among the batteries 6 due to, for example, the differences of positions where the batteries 6 are disposed. If the storage battery 2 or the like is used for a long time, for example, a battery disposed in a high-temperature region near a heat source or the like has a lower battery capacitance or a higher internal resistance than a battery disposed at a distance from the heat source or the like, and the deterioration degree of battery characteristics becomes higher. In addition, in the storage battery 2, if the management device 3 or the like determines that the life of one battery ended, the use of the storage battery 2 is terminated even if the other batteries are usable. Thus, it is required to properly replace a target battery, which is a target of replacement, before the variance of the deterioration degree of battery characteristics increases among the batteries 6, and to increase the life of the storage battery 2.

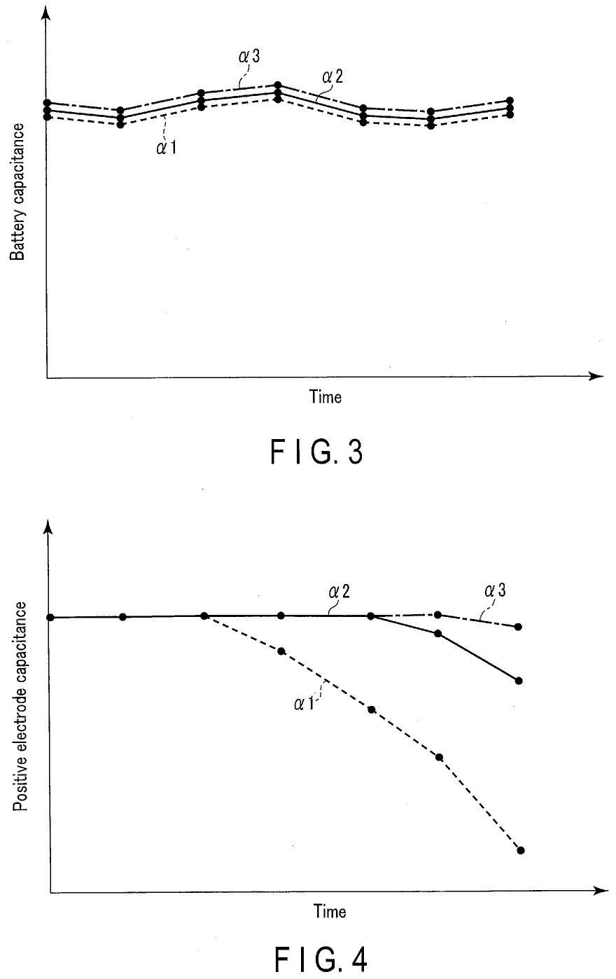

FIG. 3 is a schematic view illustrating an example of variations with time, from the start of use of a storage battery, of battery capacitances estimated in regard to three batteries of the storage battery. In addition, FIG. 4 is a schematic view illustrating variations with time, from the start of use of the storage battery, of positive electrode capacitances estimated in regard to the three batteries shown in the example of FIG. 3. In FIG. 3 and FIG. 4, the abscissa axis indicates an elapsed time from the start of use of the storage battery. The ordinate axis in FIG. 3 indicates the battery capacitance, and the ordinate axis in FIG. 4 indicates the positive electrode capacitance. In the example of FIG. 3 and FIG. 4, the positive electrode capacitance that is the internal state parameter was estimated by the above-described charge curve analysis, and the battery capacitance that is the battery characteristic parameter was estimated based on the estimated internal parameter. In addition, in the example of FIG. 3 and FIG. 4, the estimation was conducted seven times, including one time when the use of the storage battery was started, for three batteries α1 to α3, and the estimation was periodically conducted, for example, at intervals of about one year.

As shown in FIG. 3, from the first estimation time point to the last estimation time point, none of the battery capacitances of the batteries al to a3 exhibited a tendency of lowering (deterioration). Thus, even at the last estimation time point, the variance of the battery capacitance (the deterioration degree of the battery capacitance) was small among the batteries α1 toαa3. On the other hand, as shown in FIG. 4, the positive electrode capacitance of the battery α1 exhibited a tendency of lowering (deterioration) between the third estimation time point and the fourth estimation time point, and continuously lowered until the last estimation time point. In addition, the positive electrode capacitance of the battery α2 exhibited a tendency of lowering (deterioration) between the fifth estimation time point and the sixth estimation time point, and continuously lowered until the last estimation time point. Further, the positive electrode capacitance of the battery α3 exhibited a tendency of lowering (deterioration) between the sixth estimation time point and the last estimation time point. Thus, at the last estimation time point, the variance of the positive electrode capacitance (the deterioration degree of the positive electrode capacitance) was large among the batteries α1 to α3. In addition, in the example of FIG. 3 and FIG. 4, in each of the batteries α1 to α3, the positive electrode capacitance exhibited a tendency of lowering at an early stage, compared to the battery capacitance.

Similarly as in the example of FIG. 3 and FIG. 4, in the battery 6 or the like, any one of the internal state parameters, such as the positive electrode capacitance, negative electrode capacitance and SOW, exhibits a tendency of deterioration at an early stage, compared to the battery characteristic parameters such as the battery capacitance and internal resistance. In addition, in the storage battery 2 or the like, which includes the batteries 6, the timing at which the internal state parameter exhibits a tendency of deterioration varies from battery to battery, since the positions of disposition are different among the batteries and the distances from the heat source or the like are different among the batteries. Thus, in the storage battery or the like including the batteries, similarly as in the example of FIG. 3 and FIG. 4, even at a stage when the variance of the battery characteristic parameter (the deterioration degree of the battery characteristics) is small among the batteries, the variance of any one of the internal state parameters (the variance of the deterioration degree of the internal state) increases among the batteries. Specifically, in the storage battery 2 or the like, the deterioration degree of the internal state varies among the batteries 6 at an earlier stage than the deterioration degree of the battery characteristics.

In addition, in the storage battery 2 or the like, as a battery has a higher deterioration rate of the internal state, the deterioration rate of the battery characteristics thereof is higher. Specifically, as a battery has an earlier timing of exhibiting a tendency of deterioration of internal state parameters such as the positive electrode capacitance, negative electrode capacitance and SOW, the timing of exhibiting a tendency of deterioration of the battery characteristic parameters such as the battery capacitance and internal resistance is earlier. In the present embodiment, the deterioration rate data generation unit 13, replacement data generation unit 14 and effect data generation unit 15 execute processes, based on the above-described tendency of the variation with time of the battery characteristics and internal states in the batteries 6.

In regard to each of the batteries 6, the deterioration rate data generation unit 13 estimates the deterioration rate (deterioration speed) of the battery characteristics including the battery capacitance and internal resistance, based on the estimation result of the internal state by the internal state estimation unit 12. In addition, the deterioration rate data generation unit 13 generates deterioration rate data indicative of the deterioration rate of the battery characteristics in each of the batteries, which is based on the estimation result of the internal state. The deterioration rate data generation unit 13 generates the deterioration rate data at a stage when there is little variance of the battery characteristic parameter (the deterioration degree of the battery characteristics) among the batteries 6 and there is a certain degree of variance of any one of the internal state parameters (the deterioration degree of the internal state) among the batteries 6.

In one example, the deterioration rate data generation unit 13 acquires the estimation result of the positive electrode capacitance, negative electrode capacitance and SOW of each of the batteries 6. In addition, the deterioration rate data generation unit 13 estimates the deterioration rate of the battery characteristics for each battery 6, based on a parameter with a greatest variance, which is one of the positive electrode capacitance, negative electrode capacitance and SOW, among the batteries 6. Here, when the positive electrode capacitance is the parameter with the greatest variance among the batteries 6, the positive electrode capacitance of a battery among the batteries 6, which has a smallest lowering (deterioration) of the positive electrode capacitance, is set as a reference positive electrode capacitance Qaref.

Then, as regards a battery in which a difference AQa between the reference positive electrode capacitance Qaref and the positive electrode capacitance is a first threshold ΔQath1 or less, the deterioration rate of the battery characteristics is estimated as “level 1”. In addition, as regards a battery in which the difference ΔQa between the reference positive electrode capacitance Qaref and the positive electrode capacitance is greater than the first threshold ΔQath1 and is not greater than a second threshold ΔQath2, the deterioration rate of the battery characteristics is estimated as “level 2”, and the deterioration rate of the battery characteristics is estimated as being higher than the battery with the deterioration rate of “level 1”. The second threshold ΔQath2 is greater than the first threshold ΔQath1. Further, as regards a battery in which the difference ΔQa between the reference positive electrode capacitance Qaref and the positive electrode capacitance is greater than the second threshold ΔQath2, the deterioration rate of the battery characteristics is estimated as “level 3”, and the deterioration rate of the battery characteristics is estimated as being higher than the battery with the deterioration rate of “level 2”. Note that, also when either the negative electrode capacitance or the SOW is the parameter having the greatest variance among the batteries 6, like the case in which the positive electrode capacitance is the parameter having the greatest variance among the batteries 6, the deterioration rate of the battery characteristics is estimated in regard to each of the batteries 6.

Note that the deterioration rate data generation unit may estimate the deterioration rate of the battery characteristics for each battery 6, based on two or more parameters among the positive electrode capacitance, negative electrode capacitance and SOW, and may generate the deterioration rate data. In addition, the deterioration rate data generation unit 13 may estimate the deterioration rate of the battery characteristics for each battery 6, based on one of the positive electrode mass and the positive electrode capacity retention ratio, which are based on the positive electrode capacitance estimated by the internal state estimation unit 12, or may estimate the deterioration rate of the battery characteristics for each battery 6, based on one of the negative electrode mass and the negative electrode capacity retention ratio, which are based on the negative electrode capacitance estimated by the internal state estimation unit 12. Besides, the deterioration rate data generation unit 13 may estimate the deterioration rate of the battery characteristics for each battery 6, based on the internal resistance estimated by the internal state estimation unit 12, in addition to one or more parameters among the positive electrode capacitance, negative electrode capacitance, and SOW.

In addition, the deterioration rate of the battery characteristics in each of the batteries 6 does not need to be indicated by division in three levels, and may be indicated by division in, for example, five levels. Further, the deterioration rate of the battery characteristics in each battery 6 may be indicated by a rate index or the like. In this case, for example, as the rate index becomes greater, the deterioration rate of the battery characteristics in the battery is estimated to be higher. In any of the cases, however, the deterioration rate data indicates the deterioration rate of the battery characteristics in each of the batteries 6, which is based on the estimation result of one or more of the positive electrode capacitance, negative electrode capacitance and SOW, and indicates the deterioration rate of the battery characteristics in each of the batteries 6, which is based on the estimation result of the internal state.

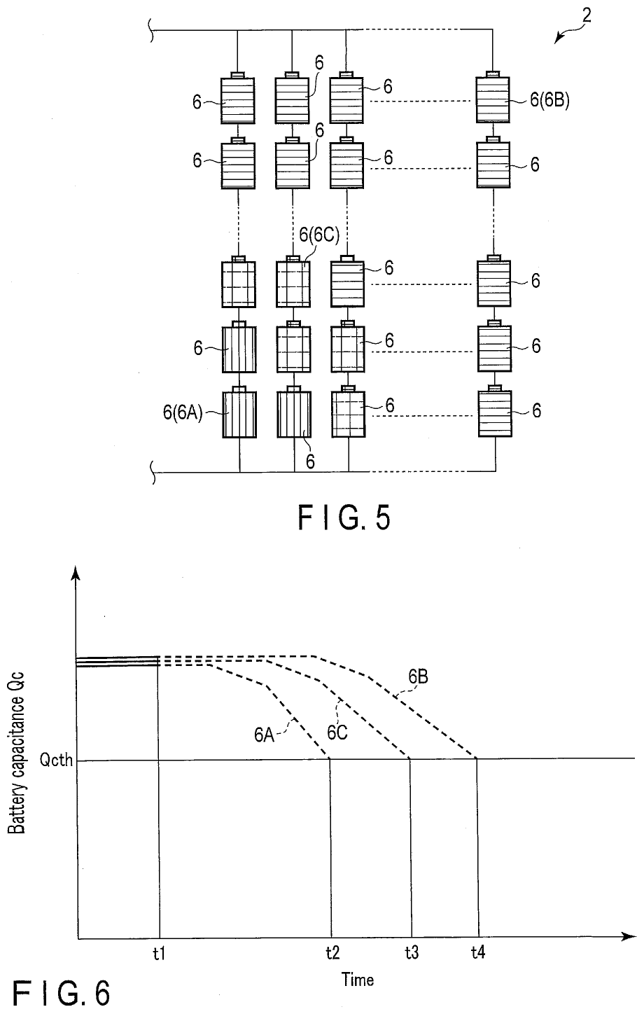

FIG. 5 is a schematic view illustrating an example of deterioration rate data which the deterioration rate data generation unit of the management device according to the embodiment generates. In the example of FIG. 5, the deterioration rate of the battery characteristics in each of the batteries 6 is estimated in the above-described three levels, based on the estimation result of the internal state by the internal state estimation unit 12. In the example of FIG. 5, a battery of “level 1”, whose deterioration rate of battery characteristics is relatively low, is indicated in blue. In addition, a battery of “level 2”, whose deterioration rate of battery characteristics is intermediate, is indicated in yellow. Further, a battery of “level 3”, whose deterioration rate of battery characteristics is relatively high, is indicated in red. In the example of FIG. 5, as regards a battery (first battery) 6A which is one of a plurality of batteries 6, the deterioration rate of battery characteristics is estimated to be “level 3”. In addition, as regards a battery (second battery) 6B which is one of the batteries 6 and is other than the battery 6A, the deterioration rate of battery characteristics is estimated to be “level 1”. Further, as regards a battery (third battery) 6C which is other than the batteries 6A and 6B among the batteries 6, the deterioration rate of battery characteristics is estimated to be “level 2”. Accordingly, in the deterioration rate data of the example of FIG. 5, the deterioration rate of the battery characteristics of the battery 6A is estimated to be higher than the deterioration rate of the battery characteristics of the battery 6C, and the deterioration rate of the battery characteristics of the battery 6B is estimated to be lower than the deterioration rate of the battery characteristics of the battery 6C.

The replacement data generation unit 14 acquires the estimation result of the internal state of each battery 6 by the internal state estimation unit 12, and the deterioration rate data generated by the deterioration rate data generation unit 13. In addition, the replacement data generation unit 14 generates replacement data, based on at least the estimation result of the internal state of each battery 6 and the deterioration rate data. The replacement data indicates information relating to a replacement work which is recommended to be performed at any time point after a time point at which the replacement data was generated. The replacement data includes information indicative of a target battery which is a target of replacement among the batteries 6, information relating to a battery with which the target battery is replaced, and information relating to a time of replacement of the target battery. Note that, after the replacement based on the replacement data, the battery, with which the target battery is replaced, is disposed at a position where the target battery was disposed.

In addition, use condition data indicative of use conditions imposed on each battery 6 in the use of the storage battery 2 may be stored in the data storage unit 16 or the like, and the replacement data generation unit 14 may acquire the use condition data. In this case, the replacement data generation unit 14 generates the replacement data, based on the use condition data, in addition to the estimation result of the internal state of each battery 6 and the deterioration rate data. The use condition data indicates, as the use conditions imposed on each battery 6 in the use of the storage battery 2, a current range (a range of a charge current value and a discharge current value), a SOC range, and a temperature range imposed on each battery 6 in the use of the storage battery 2. The use conditions greatly affect the deterioration rates of the batteries 6, and also affect the magnitude of the variation among the temperatures of the batteries 6. Accordingly, the effect by the replacement can be improved by generating the replacement data by taking into account the use conditions of the storage battery 2. The storage battery 2 is used by performing the replacement in such a state that each of the batteries 6 satisfies the above-described current range, SOC range and temperature range.

When generating the replacement data, the replacement data generation unit 14 estimates a life end time point in a case where replacement or the like is not performed, in regard to each of the batteries 6, based on at least the estimation result of the internal state and the deterioration rate data. At this time, in regard to each of the batteries 6, a reference for the end of life is set based on one or more of the battery characteristic parameters and the internal state parameters. In one example, based on the battery capacitance Qc of the elemental battery 6, a time point at which the battery capacitance Qc decreases (deteriorates) to a threshold Qcth is set as the life end time point of the battery 6. In this case, based on the estimation result of the internal state and the deterioration rate data, the replacement data generation unit 14 estimates, for each of the batteries 6, a variation with time of the battery capacitance Qc after the generation of replacement data in a case where replacement or the like is not performed. In addition, the replacement data generation unit 14 estimates, for each of the batteries 6, the time point at which the estimated variation with time of the battery capacitance Qc decreases to the threshold Qcth as the life end time point. Further, the replacement data generation unit 14 estimates an earliest time point, among the life end time points of the batteries 6, as a life end time point of the storage battery 2.

Here, among the batteries 6, a battery, in which the deterioration rate of the battery characteristics was estimated to be higher in the deterioration rate data, is set to have an earlier timing of exhibiting the tendency of deterioration (lowering) of the battery capacitance Qc in the estimated variation with time of the battery capacitance Qc, and is set to have an earlier time point at which the battery capacitance Qc decreases to the threshold Qcth. Thus, among the batteries 6, a shorter life is estimated for the battery in which the deterioration rate of the battery characteristics was estimated to be higher in the deterioration rate data. In addition, among the batteries 6, a battery, in which the deterioration degree of the internal state (internal state parameter) was estimated to be higher, is set to have an earlier timing of exhibiting the tendency of deterioration (lowering) of the battery capacitance Qc in the estimated variation with time of the battery capacitance Qc, and is set to have an earlier time point at which the battery capacitance Qc decreases to the threshold Qcth. Thus, among the batteries 6, a shorter life is estimated for the battery in which the deterioration degree of the internal state was estimated to be higher.

FIG. 6 is a schematic view for explaining an example of estimation of life end time points of a plurality of batteries in a case where the deterioration rate data of the example of FIG. 5 was generated. In FIG. 6, the abscissa axis indicates an elapsed time from the start of use of the storage battery, and the ordinate axis indicates the battery capacitance. In the example of FIG. 6, for each of the batteries 6, a variation with time of the battery capacitance Qc after the generation of replacement data in a case where replacement or the like is not performed is estimated. In addition, in regard to each of the batteries 6, a time point at which the estimated variation with time of the battery capacitance Qc decreases to the threshold Qcth is estimated as a life end time point of the battery 6. In FIG. 6, for the above-described three batteries 6A to 6C (see FIG. 5), the variations with time of the battery capacitances Qc are indicated. In the example of FIG. 6, time t1 is a time of generation of replacement data. The variations with time of the battery capacitances Qc of the batteries 6A to 6C are indicated by solid lines before time t1, and are indicated by broken line at or after time t1.

Here, in the deterioration rate data, the deterioration rate of battery characteristics of the battery 6A is estimated to be higher than the deterioration rate of battery characteristics of the battery 6C, and the deterioration rate of battery characteristics of the battery 6C is estimated to be higher than the deterioration rate of battery characteristics of the battery 6B. In addition, in the estimation of the internal state such as the positive electrode capacitance, the deterioration degree of the internal state of the battery 6A is estimated to be higher than the deterioration degree of the internal state of the battery 6C, and the deterioration degree of the internal state of the battery 6C is estimated to be higher than the deterioration degree of the internal state of the battery 6B. Thus, in the estimation of the example of FIG. 6, compared to the battery 6C, the battery 6A is set to have an earlier timing of exhibiting the tendency of deterioration (lowering) of the battery capacitance Qc, and is set to have an earlier time point at which the battery capacitance Qc decreases to the threshold Qcth. In addition, compared to the battery 6B, the battery 6C is set to have an earlier timing of exhibiting the tendency of deterioration (lowering) of the battery capacitance Qc, and is set to have an earlier time point at which the battery capacitance Qc decreases to the threshold Qcth. Accordingly, in the example of FIG. 6, time t2 is estimated as a life end time point in regard to the battery 6A, and time t3 that is later than time t2 is estimated as a life end time point in regard to the battery 6C. Further, time t4 that is later than time t3 is estimated as a life end time point in regard to the battery 6B.

Note that also when the reference for the end of life is set based on the parameter of any one of the positive electrode capacitance, negative electrode capacitance, SOW and internal resistance, for example, the variation with time of the parameter after the generation of the replacement data is estimated, and a threshold similar to the threshold Qcth of the battery capacitance Qc is set for the parameter. In addition, the time point at which the estimated variation with time of the parameter reaches the threshold is estimated as the life end time point of the battery 6. However, in the setting of the reference for the end of life based on the SOW, two thresholds are set, namely a threshold in a case where the direction of a shift of the initial charge amount of the negative electrode relative to the initial charge amount of the positive electrode is identical to the direction at the time of the start of use, and a threshold in a case where the direction of the shift of the initial charge amount of the negative electrode relative to the initial charge amount of the positive electrode is opposite to the direction at the time of the start of use. In addition, a time point at which the estimated variation with time of the SOW reaches one of the two thresholds is estimated as the life end time point of the battery 6.

Besides, no matter which of the internal state parameter or the battery characteristic parameter is the parameter that is set as the reference for the end of life, a shorter life is estimated for that battery among the batteries 6, in which the deterioration rate of the battery characteristics was estimated to be higher in the deterioration rate data. In addition, among the batteries 6, a shorter life is estimated for the battery in which the deterioration degree of the internal state is estimated to be higher.

Furthermore, in regard to each of the batteries 6, the replacement data generation unit 14 may estimate the life end time point in a case where replacement or the life is not performed, based on the use condition data, in addition to the estimation result of the internal state and the deterioration rate data. In this case, temperature distribution data indicative of a temperature distribution in an environment (space), in which the batteries 6 are arranged, is generated based on the deterioration rate data and the above-described temperature range which is imposed on each battery 6 as the use condition. Then, based on the temperature distribution data, the replacement data generation unit 14 estimates the life end time point of each of the batteries 6. In the temperature distribution data, the temperature of a region where the battery, which was estimated to have a higher deterioration rate of battery characteristics, is disposed is higher than the temperatures of other regions. Accordingly, in the temperature distribution data based on the deterioration rate data of the example of FIG. 5, the temperature of a region or the like where the battery 6A is disposed is higher than the temperatures of a region or the like where the battery B is disposed and a region or the like where the battery C is disposed.

The replacement data generation unit 14 generates replacement data, based on the estimation result of the life end time point in regard to each of the batteries 6. In one example, the replacement data generation unit 14 selects a target battery, which is a target of replacement, from among the batteries 6, based on the estimation result of the life end time point. In this case, a target life of the storage battery 2 is stored in the data storage unit 16. In the replacement data that the replacement data generation unit 14 generates, at least a battery, whose estimated life end time point is shorter than the target life, is included in target batteries. Note that if all batteries, whose estimated life end time points are shorter than the target life, are included in the target batteries that are targets of replacement, a battery, whose estimated life end time point is equal to or longer than the target life, may be included in the target batteries.

For example, it is assumed that the life end time point of each of the batteries 6 was estimated based on the deterioration rate data of the example of FIG. 5. In addition, for example, it is assumed that batteries including the battery 6A, whose deterioration rates of battery characteristics were estimated to be “level 3”, were estimated to have life end time points which are shorter than the target life. In this case, at least the batteries whose deterioration rates of battery characteristics were estimated to be “level 3”, i.e. at least the batteries indicated in red in the deterioration rate data of FIG. 5, are selected as target batteries that are targets of replacement. In addition, batteries, whose deterioration rates of battery characteristics were estimated to be “level 1” or “level 2”, may be included as target batteries.

In the replacement data generated by the replacement data generation unit 14, a battery, with which the target battery is replaced, and a time of replacement of the target battery, are determined in such a state that the life of the storage battery 2 becomes the above-described target life or more. Specifically, the replacement data is generated in such a state that the life of the storage battery 2 becomes the target life or more by the replacement of the target battery based on the replacement data. Thus, by performing the replacement of the target battery, based on the replacement data, even the battery having a shortest life among the batteries 6 will have a life of the target life or more. In addition, it is preferable that, on condition that the life of the storage battery 2 becomes the above-described target life or more, the battery with which the target battery is replaced, and the time of replacement of the target battery, are determined in such a state that the life of the storage battery 2 becomes as long as possible.

In one example, the replacement data indicates that a battery, whose life end time point was estimated to be an earliest time point among the batteries 6, is replaced with a battery whose life end time point was estimated to be a latest time point among the batteries 6. In this case, by the replacement of the target battery based on the replacement data, the positions of batteries 6 of the storage battery 2 are interchanged.

For example, it is assumed that the deterioration rate data of the example of FIG. 5 was generated, and that at least batteries, whose deterioration rates of battery characteristics were estimated to be “level 3”, were selected as target batteries that are targets of replacement. In addition, it is assumed that, among the batteries 6, the life end time point of the battery 6A was estimated as the earliest time point, and the life end time point of the battery 6B was estimated as the latest time point. In this case, the replacement data indicates that the battery (first battery) 6A that is the target battery is replaced with the battery (second battery) 6B. Accordingly, by performing the replacement of the target battery, based on the replacement data, the battery 6A, whose life was estimated to be shorter than the battery (third battery) 6C or the like, is replaced with the battery 6B whose life was estimated to be longer than the battery 6C or the like.

In addition, in one example, the replacement data generation unit 14 specifies a parameter with a highest deterioration degree among the internal state parameters estimated by the internal state estimation unit 12, in regard to each of the target batteries that are targets of replacement. In this case, a parameter with a highest deterioration degree among the positive electrode capacitance, negative electrode capacitance and SOW may be specified, or a parameter with a highest deterioration degree among the positive electrode capacitance, negative electrode capacitance and SOW and, additionally, the internal resistance, may be specified. In addition, the replacement data indicates that each of the target batteries is replaced with a battery whose deterioration degree of the specified parameter is relative low among the batteries 6. In this case, too, by the replacement of the target battery based on the replacement data, the positions of the batteries 6 of the storage battery 2 are interchanged.

For example, it is assumed that the deterioration rate data of the example of FIG. 5 was generated, and at least the batteries, whose deterioration rates of battery characteristics were estimated to be “level 3”, were selected as target batteries that are targets of replacement. In addition, it is assumed that, in the battery 6A that is one of the target batteries, the positive electrode capacitance was specified as a parameter with a highest deterioration degree among the internal state parameters. In this case, the replacement data indicates that the battery (first battery) 6A that is the target battery is replaced with the battery (second battery) 6B whose deterioration degree of the positive electrode capacitance is relatively low. Accordingly, by performing the replacement of the target battery, based on the replacement data, the battery 6A, whose deterioration degree of the positive electrode capacitance was estimated to be higher than the battery (third battery) 6C or the like, is replaced with the battery 6B whose deterioration degree of the positive electrode capacitance was estimated to be lower than the battery 6C or the like.

In addition, the replacement data is generated by taking into account the case in which each of the batteries 6 is used at an upper-limit value or near the upper-limit value in the above-described temperature range that is imposed as the use condition, i.e. the case in which the storage battery 2 is used in a high-temperature environment. For example, when the storage battery 2 is used at the upper-limit value of the temperature range that is imposed as the use condition, the replacement data is generated in such a state that the temperature rise due to the current becomes the target value or less in any of the batteries 6. Thus, at the time of the replacement, or immediately after the replacement, of the target battery based on the replacement data, the temperature rise due to the current becomes the target value or less as long as the storage battery 2 (the batteries 6) is used in the temperature range imposed as the use condition. Further, it is preferable that, on condition that the temperature rise due to the current becomes the target value or less in any of the batteries 6 in the use of the storage battery 2 in the high-temperature environment, the battery, with which the target battery is replaced, and the time of replacement of the target battery, are determined in such a state that the temperature rise due to the current in each battery 6 becomes as low as possible.

Besides, the replacement data is generated by taking into account the case in which each of the batteries 6 is used at a lower-limit value or near the lower-limit value in the above-described temperature range that is imposed as the use condition, i.e. the case in which the storage battery 2 is used in a low-temperature environment. For example, when the storage battery 2 is used at the lower-limit value of the temperature range that is imposed as the use condition, the replacement data is generated in such a state that the output characteristic of the storage battery 2 becomes the target level or more. Thus, at the time of the replacement, or immediately after the replacement, of the target battery based on the replacement data, the output characteristic of the storage battery 2 becomes the target level or more, for example, such that the output power of the storage battery 2 becomes the target value or more, as long as the storage battery 2 (the batteries 6) is used in the temperature range imposed as the use condition. Further, it is preferable that, on condition that the output characteristic of the storage battery 2 becomes the target level or more in the use of the storage battery 2 in the low-temperature environment, the battery, with which the target battery is replaced, and the time of replacement of the target battery, are determined in such a state that the output characteristic of the storage battery 2 becomes as high as possible.

When it is not possible to increase the life of the storage battery 2 to the target life or more by only the interchange of the positions of batteries 6 of the storage battery 2, the replacement data indicates that at least a part of the target batteries that are targets of replacement is replaced with a predetermined battery other than the batteries 6 of the storage battery 2. In this case, a battery of the same kind as the batteries 6 is used as the battery with which the target battery is replaced. The battery, with which the target battery is replaced, may be a new battery of the same kind as the batteries 6, or may be a battery which has been used in a device different from the battery-mounted device in which the storage battery 2 is mounted, and whose estimation result of the internal state was acquired.

Furthermore, there is a case in which it is not possible to meet at least one of the above-described condition in the use of the storage battery 2 in the high-temperature environment and the above-described condition in the use of the storage battery 2 in the low-temperature environment, by only the interchange of the positions of the batteries 6 of the storage battery 2. In this case, too, the replacement data indicates that at least a part of the target batteries that are targets of replacement is replaced with a predetermined battery other than the batteries 6 of the storage battery 2. In addition, when a plurality of target batteries that are targets of replacement are selected, it is preferable that, from the standpoint of an improvement in work efficiency of the replacement work, replacement data in which the replacement times of the target batteries are identical is generated.

Besides, there is a case in which the replacement data indicates that a target battery that is a target of replacement is replaced with a battery of a battery string 5 that is different from the battery string 5 of the target battery in the storage battery 2. In this case, the replacement data may indicate that the balance of the SOC among the batteries 6 is adjusted at the time of replacing the target battery. For example, when the deterioration rate data of the example of FIG. 5 is generated and the replacement of the battery 6A with the battery 6B is indicated in the replacement data, the replacement data indicates that the balance of the SOC is adjusted between the batteries of the battery string 5, in which the battery 6A was disposed, and the batteries of the battery string 5, in which the battery 6B was disposed. By adjusting the balance of the SOC between the batteries 6 at the time of replacing the target battery, the variance of the SOC among the batteries 6 can be kept small, even if the target battery is replaced with the battery of the battery string 5 that is different from the battery string 5 of the target battery.

The effect data generation unit 15 acquires the estimation result of the internal state of each of the batteries 6, the deterioration rate data generated by the deterioration rate data generation unit 13, and the replacement data generated by the replacement data generation unit 14. In addition, the effect data generation unit 15 generates effect data, based on the above-described data that was acquired. The effect data indicates an effect in a case where the replacement of the target battery based on the replacement data is performed. In one example, the effect data indicates the effect in the case where the replacement of the target battery based on the replacement data is performed, as compared to the case where the replacement of the target battery is not performed. The effect data includes, for example, information indicating that the life of the storage battery 2 is extended by the replacement of the target battery based on the replacement data.

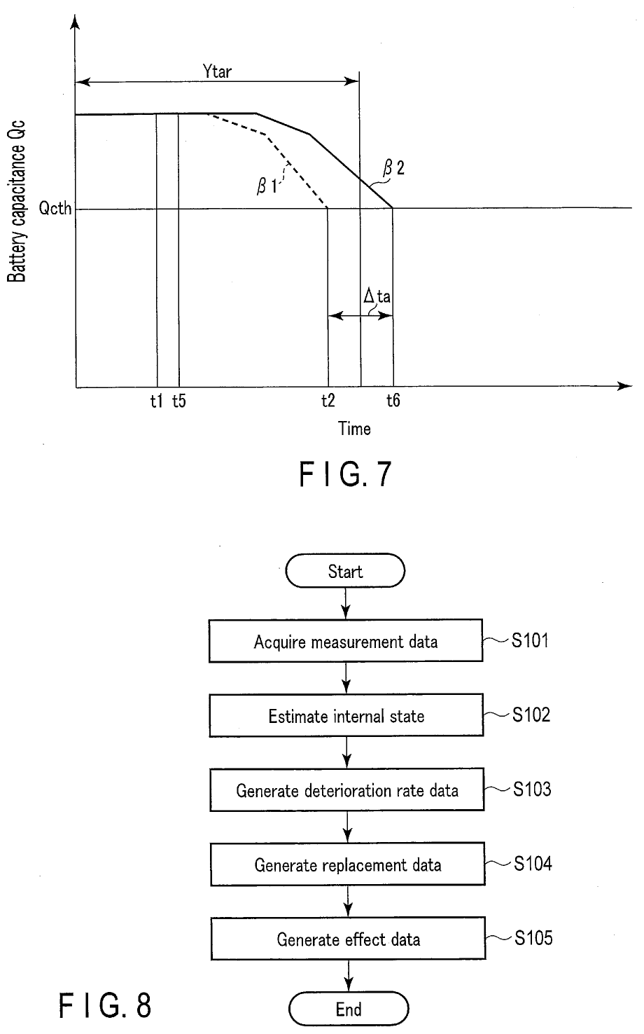

FIG. 7 is a schematic view illustrating an example of effect data in a case where replacement data was generated based on the deterioration rate data of the example of FIG. 5. In FIG. 7, the abscissa axis indicates an elapsed time from the start of use of the storage battery 2, and the ordinate axis indicates the battery capacitance Qc. In addition, in FIG. 7, time t1 is a time of generation of replacement data. In the example of FIG. 7, as regards the battery 6A which is the target battery that is the target of replacement, an estimation result of the variation with time of the battery capacitance Qc in the case where the replacement is not performed is indicated by a broken line β1. Besides, in the example of FIG. 7, as regards the battery 6A, an estimation result of the variation with time of the battery capacitance Qc in the case where the replacement of the target battery based on the replacement data is conducted is indicated by a solid line β2. In the example of FIG. 7, in regard to each of the batteries 6, a time point at which the estimated variation with time of the battery capacitance Qc lowers to the threshold Qcth is estimated as a life end time point.

In the example of FIG. 7, in each of the case where the replacement of the battery 6 is not performed and the case where the replacement of the target battery based on the replacement data is performed, it is estimated that the battery capacitance Qc of the battery 6A among the batteries 6 lowers earliest to the threshold Qcth. Thus, in each of the case where the replacement of the battery 6 is not performed and the case where the replacement of the target battery based on the replacement data is performed, the life of the battery 6A among the batteries 6 is estimated to be shortest, and the life end time point of the battery 6A is estimated to be the life end time point of the storage battery 2. If the replacement of the battery 6 is not conducted, as described above, time t2 is estimated as the life end time point of the battery 6A, and estimated as the life end time point of the storage battery 2. Thus, the effect data indicates that the life of the storage battery 2 becomes shorter than a target life Ytar if the replacement of the battery 6 is not conducted.

In addition, in the example of FIG. 7, if the replacement of the target battery based on the replacement data is conducted at time t5 that is later than time t1, time t6 that is later than time t2 is estimated as the life end time point of the battery 6A, and estimated as the life end time point of the storage battery 2. Thus, the effect data indicates that the life of the storage battery 2 is extended by an extension time £ta by the replacement of the target battery based on the replacement data. In addition, the effect data indicates that the life of the storage battery 2 becomes the target life Ytar or more by the replacement of the target battery based on the replacement data. Note that, as described above in connection with the replacement data, the reference for the end of life may be set based on the parameter of any one of the positive electrode capacitance, negative electrode capacitance, SOW and internal resistance, in place of the battery capacitance or in addition to the battery capacitance.

Additionally, the effect data may indicate that the period, during which the above-described condition is satisfied in the use of the storage battery 2 in the high-temperature environment, becomes longer in the case where the replacement of the target battery based on the replacement data is performed, compared to the case where the target battery is not replaced. In this case, for example, the effect data indicates that the period, during which the temperature rise due to the current in each of the batteries becomes the target value or less, becomes longer by the replacement of the target battery, in the use of the storage battery 2 (the batteries 6) at the upper-limit value of the temperature range imposed as the use condition. Further, the effect data may indicate that the period, during which the above-described condition is satisfied in the use of the storage battery 2 in the low-temperature, becomes longer if the replacement of the target battery based on the replacement data is performed, compared to the case where the target battery is not replaced. In this case, for example, the effect data indicates that the period, during which the output characteristic of the storage battery 2 becomes the target level or more, becomes longer by the replacement of the target battery, in the use of the storage battery 2 (the batteries 6) at the lower-limit value of the temperature range imposed as the use condition.

Additionally, the effect data may indicate a cost which occurs when the replacement of the target battery based on the replacement data is performed. In this case, the effect data generation unit 15 may determine whether the replacement of the target battery based on the replacement data is feasible from the aspect of cost. In this case, information or the like relating to the cost for the user of the battery-mounted device, in which the storage battery 2 is mounted, is stored in the data storage unit 16. In addition, the effect data may indicate a determination result as to whether the replacement of the target battery based on the replacement data is feasible from the aspect of cost.

Note that the management device 3 may store, in the data storage unit 16, the deterioration rate data, replacement data and effect data which were generated as described above. Further, the management device 3 may be capable of notifying the user or the like of the battery-mounted device, in which the storage battery 2 is mounted, of the deterioration rate data, replacement data and effect data generated as described above, via a user interface or the like. In this case, the replacement data and the like may be notified by voice, or may be notified by screen display or the like.

FIG. 8 is a flowchart illustrating a process which is executed by the management device according to the embodiment. The process of FIG. 8 is executed once or more times at a predetermined timing. In one example, the process of FIG. 8 is automatically executed at a predetermined timing before the variance of the deterioration degree of battery characteristics among the batteries 6 increases. In another example, the process of FIG. 8 is executed based on the input of an operation instruction through a user interface by the user or the like of the battery-mounted device in which the storage battery 2 is mounted.

If the process of FIG. 8 is started, the measurement data acquisition unit 11 of the management device 3 acquires the above-described measurement data (S101). Then, the internal state estimation unit 12 estimates the internal state (internal state parameter) of each of the batteries 6, as described above (S102). Further, the deterioration rate data generation unit 13 estimates the deterioration rate of battery characteristics, based on the estimation result of the internal state, in regard to each battery 6. In addition, the deterioration rate data generation unit 13 generates the above-described deterioration rate data indicative of the deterioration rate of the battery characteristics in each of the batteries 6 (S103).

Subsequently, the replacement data generation unit 14 generates the above-described replacement data, based on at least the estimation result of the internal state of each of the batteries 6, and the deterioration rate data (S104). The replacement data includes the information indicative of the target battery that is the target of replacement among the batteries 6, the information relating to the battery with which the target battery is replaced, and the information relating to the time of replacement of the target battery. Further, the effect data generation unit 15 generates the effect data indicative of the effect in the case where the replacement of the target battery based on the replacement data is performed (S105).

In the present embodiment, the replacement data is generated based on at least the estimation result of the internal state of each of the batteries 6, and the deterioration rate data indicative of the deterioration rate of the battery characteristics in each battery 6, the deterioration rate data being based on the estimation result of the internal state. Thus, the replacement data can be generated before the variance of the deterioration degree of the battery characteristics increases among the batteries 6 increases, and the target battery can be replaced based on the replacement data, before the variance of the deterioration degree of the battery characteristics increases among the batteries 6 increases.

Additionally, the replacement data includes the information indicative of the target battery that is the target of replacement among the batteries 6, the information relating to the battery with which the target battery is replaced, and the information relating to the time of replacement of the target battery. In the present embodiment, since the replacement data is generated based on the estimation result of the internal state of each of the batteries 6, and the deterioration rate data, the replacement data is properly generated, for example, with the target battery that is the target of replacement being properly selected. Thus, by replacing the target battery, based on the replacement data, the target battery is properly replaced. Accordingly, in the present embodiment, the target battery that is the target of replacement can appropriately be replaced before the variance of the deterioration degree of battery characteristics increases among the batteries 6 in the storage battery 2.

Additionally, in the present embodiment, the replacement data indicates that the position of the target battery is interchanged with the position of another battery of the storage battery 2, except for a case in which the life of the storage battery 2 cannot be extended to the target life or more by only the interchange of the positions of batteries 6 of the storage battery 2. Since the replacement of the target battery based on the replacement data is the interchange of positions of batteries 6 of the storage battery 2, there is no need to add a new battery in the replacement work, and the labor and cost of the replacement work can be reduced. In addition, for example, even when it is difficult to obtain a battery of the same kind as the batteries 6, the replacement of the target battery based on the replacement data is properly performed. Further, when the replacement of the target battery based on the replacement data is the interchange of positions of batteries 6 of the storage battery 2, the variance of battery characteristics among the batteries 6 can be kept small for a long time by replacing the target battery, based on the replacement data. Therefore, the life of the storage battery 2 can be extended.

Additionally, in the present embodiment, the replacement data is generated in such a state that the life of the storage battery 2 becomes the target life (Ytar) or more by the replacement of the target battery based on the replacement data. Thus, by replacing the target battery, based on the replacement data, the life of the storage battery 2 can properly be extended. Further, by replacing the target battery, based on the replacement data, an excessive temperature rise due to the current in each battery 6 can properly be suppressed even when the storage battery 2 is used in a high-temperature environment. Besides, by replacing the target battery, based on the replacement data, the output characteristic of the output from the storage battery can properly be ensured even when the storage battery 2 is used in a low-temperature environment.

Additionally, by the generation of the replacement data, the user or the like of the battery-mounted device in which the storage battery 2 is mounted can properly prepare for the replacement work. For example, even when the replacement data indicates that at least a part of target batteries is replaced with a predetermined battery other than the batteries 6 of the storage battery 2, a battery with which the target battery is replaced can properly be prepared. Besides, by the generation of the replacement data, it is possible to properly prepare for the cost or the like relating to the replacement work, before the replacement work.

Additionally, in the present embodiment, the effect data indicative of the effect in the case where the replacement of the target battery based on the replacement data is performed is generated. Thus, the user or the like of the battery-mounted device, in which the storage battery is mounted, can properly understand the effect in the case where the replacement of the target battery based on the replacement data is conducted.

Note that, in the above-described embodiments and the like, the management device 3 is a computer (server) that is different from the charge-and-discharge controller 8, or a server in a cloud environment, the management device 3 is not limited to this. In one embodiment, the charge-and-discharge controller 8 may generate the above-described replacement data, effect data and the like. In this case, the charge-and-discharge controller 8 generates the replacement data and the like by executing the same process as the management device 3 of the above-described embodiment.

In at least one of the above-described embodiments and examples, replacement data is generated based on at least an estimation result of an internal state of each of a plurality of batteries, and deterioration rate data indicative of a deterioration rate of battery characteristics in each of the batteries, the deterioration rate data being based on the estimation result of the internal state. The replacement data includes information indicative of a target battery which is a target of replacement among the batteries, information relating to a battery with which the target battery is replaced, and information relating to a time of replacement of the target battery. Thereby, there can be provided a management method, a management device, a management system and a management program, which enables proper replacement of the target battery that is the target of replacement, before the variance of the deterioration degree of battery characteristics increases among the batteries in the storage battery.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A management method of a storage battery including a plurality of batteries, comprising:
generating replacement data, based on at least an estimation result of an internal state of each of the batteries, and deterioration rate data indicative of a deterioration rate of battery characteristics in each of the batteries, the deterioration rate data being based on the estimation result of the internal state, the replacement data including information indicative of a target battery which is a target of replacement among the batteries, information relating to a battery with which the target battery is replaced, and information relating to a time of replacement of the target battery, the replacement data being generated at a timing when the battery characteristics in each of the batteries do not exhibit a tendency of deterioration and the internal state in any one or more of the batteries exhibits a tendency of deterioration.

2. The management method of claim 1, wherein
the replacement data is generated based on at least the deterioration rate data indicative of the deterioration rate of the battery characteristics in each of the batteries, the deterioration rate data being based on an estimation result of one or more of a positive electrode capacitance, a negative electrode capacitance and an SOW.

3. The management method of claim 1, wherein
the replacement data includes information indicating that a first battery, which is one of the target batteries, is replaced with a second battery which is one of the batteries and is different from the first battery.

4. The management method of claim 3, wherein
in the deterioration rate data, the deterioration rate of the battery characteristics of the first battery is estimated to be higher than the deterioration rate of the battery characteristics of a third battery which is one of the batteries and is different from the first battery and the second battery, and
in the deterioration rate data, the deterioration rate of the battery characteristics of the second battery is estimated to be lower than the deterioration rate of the battery characteristics of the third battery.

5. The management method of claim 1, wherein
the replacement data is generated in such a state that a life of the storage battery becomes a target life or more by the replacement of the target battery based on the replacement data.

6. The management method of claim 1, wherein
the replacement data is generated based on use condition data indicative of a use condition imposed on each of the batteries in use of the storage battery, in addition to the estimation result of the internal state of each of the batteries, and the deterioration rate data.

7. The management method of claim 1, further comprising:
generating effect data indicative of an effect in a case where the replacement of the target battery based on the replacement data is performed.

8. The management method of claim 1, further comprising:
generating effect data including information indicating that a life of the storage battery is extended by the replacement of the target battery based on the replacement data.

9. A management device of a storage battery including a plurality of batteries, comprising:
a processor configured to generate replacement data, based on at least an estimation result of an internal state of each of the batteries, and deterioration rate data indicative of a deterioration rate of battery characteristics in each of the batteries, the deterioration rate data being based on the estimation result of the internal state, the replacement data including information indicative of a target battery which is a target of replacement among the batteries, information relating to a battery with which the target battery is replaced, and information relating to a time of replacement of the target battery, the replacement data being generated at a timing when the battery characteristics in each of the batteries do not exhibit a tendency of deterioration and the internal state in any one or more of the batteries exhibits a tendency of deterioration.

10. A management system comprising:
the management device of claim 9; and
the storage battery which includes the plurality of batteries, the replacement data relating to the batteries being generated by the processor of the management device.

11. A non-transitory storage medium storing a management program of a storage battery including a plurality of batteries, the management program causing a computer to execute:
generating replacement data, based on at least an estimation result of an internal state of each of the batteries, and deterioration rate data indicative of a deterioration rate of battery characteristics in each of the batteries, the deterioration rate data being based on the estimation result of the internal state, the replacement data including information indicative of a target battery which is a target of replacement among the batteries, information relating to a battery with which the target battery is replaced, and information relating to a time of replacement of the target battery, the replacement data being generated at a timing when the battery characteristics in each of the batteries do not exhibit a tendency of deterioration and the internal state in any one or more of the batteries exhibits a tendency of deterioration.
